(19) United States
(12) Patent Application Publication
(10) Pub. No.: US 2026/0338943 A1
(43) Pub. Date: Oct. 29, 2026

(54) RADIO FREQUENCY COMMUNICATION SYSTEM FOR DETECTING POSTURE OF OBJECT

(71) Applicant: OWLYNK CO., LTD., Suwon-si (KR)

(72) Inventor: Shin Hwan HWANG, Yongin-si (KR)

(73) Assignee: OWLYNK CO., LTD., Suwon-si (KR)

(21) Appl. No.: 19/461,762

(22) Filed: Jan. 28, 2026

(30) Foreign Application Priority Data
Jan. 31, 2025 (KR) 10-2025-0012356

(51) Int. Cl. G01S 13/88; G01S 7/41; H01Q 15/04; H01Q 15/14; H03C 7/02

(52) U.S. Cl. CPC G01S 13/88; G01S 7/41; H01Q 15/04; H01Q 15/14; H03C 7/02

(57) ABSTRACT

The present disclosure relates to a radio frequency communication system, and in order to accurately detect not only the position of an object but also the posture of the object, a modulator is disposed on a signal guide line to frequency-modulate and reflect a plurality of radio frequency signals incident on a plurality of reflector antennas.

### CROSS-REFERENCE TO RELATED APPLICATION(S)

This application claims priority to and the benefit of Korean Patent Application No. 10-2025-0012356, filed on Jan. 31, 2025, in the Korean Intellectual Property Office, the disclosure of which is incorporated herein by reference in its entirety.

### BACKGROUND

### 1. Field

The present disclosure relates to a radio frequency communication system.

### 2. Description of Related Art

Beamforming technology has been introduced, in which radio frequency signals are concentrated in a specific direction and transmitted to a receiving device using a plurality of transmit antennas, rather than transmitting radio frequency signals in multiple directions.

Technologies have been developed to ensure that when a receiving device transmits radio frequency signals to a transmitting device or another device through a plurality of receive antennas, the radio frequency signals are in phase so that strong signals are transmitted.

U.S. Pat. No. 2,908,002, titled “ELECTROMAGNETIC REFLECTOR,” invented by Van Atta and commonly referred to as VARA, disclosed a passive reflector device that connects horn antennas with wave guide sections having predetermined lengths and appropriately sets the lengths of the wave guide sections to reflect a plurality of radio frequency signals in phase to a transmitting device or in a predetermined direction.

Through this, separate switching control for in-phase operation using power is no longer required.

However, with the introduction of digital twin, metaverse, cyber-physical systems (CPS), and the like, there is an increasing need to detect and output the posture of an object, including not only the current position and distance of the object but also its orientation, positioning, and the like.

### SUMMARY

The present disclosure aims to accurately detect not only the position of an object but also the posture of the object.

According to an aspect of the present disclosure, a modulator is disposed on a signal guide line to frequency-modulate and reflect a plurality of radio frequency signals incident on a plurality of reflector antennas.

According to an additional aspect of the present disclosure, the reflected radio frequency signal is demodulated and the phase difference thereof is calculated to accurately detect the posture or orientation of the object.

According to the present disclosure, not only the position of an object but also the posture or orientation thereof can be accurately detected.

The present disclosure can be applied to various technical fields such as digital twin, metaverse, cyber-physical systems (CPS), or motion capture to accurately match the posture, position, orientation, and the like of a real object to a virtual world.

### BRIEF DESCRIPTION OF THE DRAWINGS

FIG. 1 illustrates a radio frequency communication system for detecting a posture of an object, including a transceiver device and a reflector device, according to an embodiment.

FIG. 2 illustrates a reflector device according to an embodiment.

FIG. 3 illustrates a reflector device according to another embodiment.

### DETAILED DESCRIPTION OF THE EMBODIMENTS

The foregoing and additional aspects are embodied through embodiments described with reference to the accompanying drawings.

It is understood that the components of each embodiment can be variously combined within an embodiment or with components of other embodiments unless otherwise stated or contradicted.

Based on the principle that an inventor can appropriately define the concept of a term to best describe his or her own invention, the terms used in this specification and the claims should be interpreted with meanings and concepts consistent with the described content or the proposed technical idea.

Blocks expressed as “circuits” in this specification may be configured as hardware such as dedicated semiconductors, gate arrays, FPGAs, or parts thereof.

One or more blocks may be implemented as a single piece of hardware.

As another example, these blocks may be implemented in software as an information processing device in which a computing element executes executable instructions stored in a memory element.

A plurality of blocks may be implemented as part of a program executed on the same computing element.

As another example, these blocks may be implemented in a hybrid form in which some of the individual circuits are hardware and some are software.

Also, in a software implementation, the computing element may include digital signal processors, dedicated computing processors, artificial intelligence processing engines, artificial intelligence dedicated processors, graphics processors, or combinations thereof to the extent possible.

Hereinafter, preferred embodiments of the present disclosure will be described in detail with reference to the accompanying drawings.

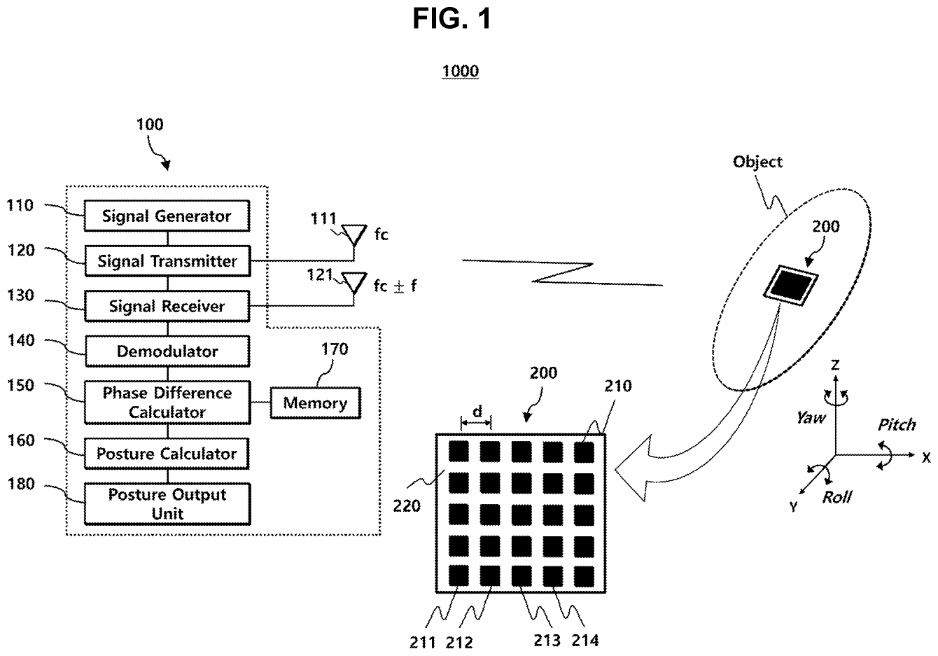

FIG. 1 illustrates a radio frequency communication system for detecting a posture of an object, including a transceiver device and a reflector device, according to an embodiment.

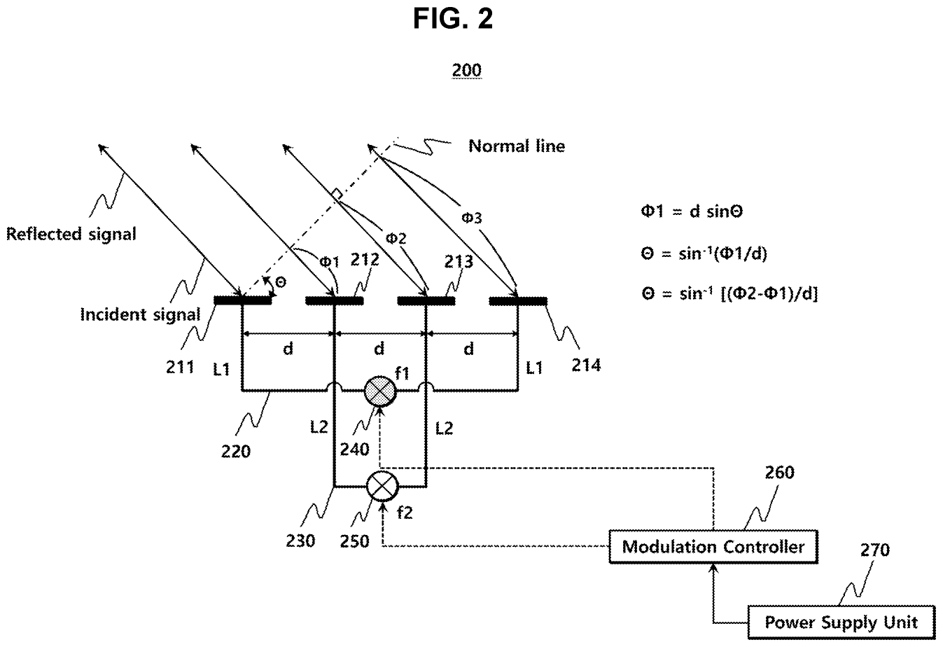

FIG. 2 illustrates a reflector device according to an embodiment.

According to an embodiment, a radio frequency communication system 1000 for detecting a posture of an object includes a transceiver device 100 and a reflector device 200.

As shown in FIG. 1, the transceiver device 100 includes a signal generator 110 and a signal transmitter 120, and as shown in FIG. 2, the reflector device 200 includes a reflector antenna array 210, a first signal guide line 220, a second signal guide line 230, a first modulator 240, and a second modulator 250.

In the transceiver device 100, the signal generator 110 may generate a radio frequency signal. The radio frequency signal may have a specific frequency band (fc).

For example, the radio frequency signal may have a 2.4 GHz frequency band, but is not limited thereto. The radio frequency signal may be configured as a frequency-modulated continuous wave (FMCW), but is not limited thereto.

The signal transmitter 120 includes a transmit antenna 111 and may transmit the radio frequency signal toward the reflector device 200. The radio frequency signal transmitted from the transmit antenna 111 may have a specific frequency band (fc) as mentioned above. The transmit antenna 111 may be one or more.

The transceiver device 100 has a power supply source (not shown) that supplies power to each component or part.

In the reflector device 200, the reflector antenna array 210 is arranged at equal intervals on a substrate 220 and may include a first reflector antenna 211, a second reflector antenna 212, a third reflector antenna 213, and a fourth reflector antenna 214. The reflector antenna array 210 includes a plurality of reflector antennas, and the plurality of reflector antennas may be arranged at equal intervals (d) from each other.

The plurality of reflector antennas may be deployed in a straight line at equal intervals. When the transceiver device 100 and the reflector device 200 have a sufficient distance, a plurality of transmitted radio frequency signals incident on the plurality of reflector antennas may represent a field of observation parallel to each other.

The plurality of reflector antennas may be arranged in two dimensions (2D) to form the reflector antenna array 210. The substrate 220 may be a PCB. It is preferable that the plurality of reflector antennas are arranged on a planar substrate.

The first reflector antenna 211, the second reflector antenna 212, the third reflector antenna 213, and the fourth reflector antenna 214 constitute the reflector antenna array 210, and all reflector antennas of the reflector antenna array 210 may be the first reflector antenna 211, the second reflector antenna 212, the third reflector antenna 213, or the fourth reflector antenna 214.

There is no limitation on the type of reflector antenna constituting the reflector antenna array 210, and it may preferably be a patch antenna. Patch antennas are small in volume and advantageous for transmitting radio waves in a specific direction.

The reflector device 200 may be used by being attached to an object. Accordingly, the reflector device 200 can follow the posture of the object as is. The object may be a stationary object or a moving object. The object may be a person, an animal, a weapon, a vehicle, an aircraft, or the like, and there is no limitation on the type of object.

In FIG. 2, the first signal guide line 220 electrically connects the first reflector antenna and the fourth reflector antenna and may have a predetermined length. The second signal guide line 230 electrically connects the second reflector antenna and the third reflector antenna and may have a predetermined length.

The length of the first signal guide line 220 may be the same as or different from the length of the second signal guide line 230, and may have an appropriate length so that the radio frequency signal can be reflected and transmitted in the same phase. The first signal guide line 220 and the second signal guide line 230 are electrically isolated from each other.

The first modulator 240 is disposed on the first signal guide line 220 and may frequency-modulate a radio frequency signal incident on the first reflector antenna 211 or the fourth reflector antenna 214. The modulated radio frequency signal may be transmitted to the transceiver device 100 through the fourth reflector antenna 214 or the first reflector antenna 211.

The second modulator 250 is disposed on the second signal guide line 230 and may frequency-modulate a radio frequency signal incident on the second reflector antenna 212 or the third reflector antenna 213.

The meaning that the first modulator 240 is disposed “on” the first signal guide line 220 is that it is sufficient if it can be appropriately arranged so that the frequency signal input to the first modulator 240 is output with a specific frequency (f1) added, subtracted, or multiplied. Therefore, it includes the first modulator 240 being disposed between a plurality of first signal guide lines 220.

Similarly, it is sufficient if the second modulator 250 can also be appropriately arranged so that the frequency signal input to the second modulator 250 is output with a specific frequency (f2) added, subtracted, or multiplied. Therefore, it includes the second modulator 250 being disposed between a plurality of second signal guide lines 230.

It is sufficient for the first modulator 240 and the second modulator 250 to perform a function of modulating frequency, and they may be implemented in various ways, such as being configured with PIN diodes or switches.

For example, the first modulator 240 and the second modulator 250 may modulate the frequency by a switching method that repeats short-circuit/open of the first signal guide line 220 and the second signal guide line 230 according to a predetermined time slot, or may modulate the frequency by directly adding or subtracting a specific frequency.

In the former case, the first modulator 240 and the second modulator 250 may be sequentially activated, and in the latter case, the first modulator 240 and the second modulator 250 may be simultaneously activated.

The meaning of being activated may mean a state (ON) in which the modulation function is performed. According to an additional aspect, in FIG. 1, the transceiver device 100 may further include a signal receiver 130, a demodulator 140, a phase difference calculator 150, and a posture calculator 160.

The signal receiver 130 includes a receive antenna 121 and may receive a frequency-modulated radio frequency signal from the reflector device 200. The receive antenna 121 may be one or more.

The demodulator 140 may demodulate the frequency-modulated radio frequency signal. For example, the demodulator 140 may separate a transmit signal frequency (fc) and other frequencies (f) from the reflected radio frequency signal, that is, the modulated radio frequency signal.

The other frequencies (f) may be f1 and f2 in FIG. 2. f1 and f2 may be considerably smaller than the transmit signal frequency (fc). For example, when the transmit signal frequency (fc) is 2.4 GHz, f1 and f2 may have a frequency range of several KHz to several tens of KHz, and f1 and f2 may be different from each other (f1≠f2). For example, f2=2f1. As such, because f1 and f2 are considerably smaller than the transmit signal frequency (fc), the transmission and reception characteristics of the transceiver device 100 to which a specific frequency band is generally applied may not be impaired.

The phase difference calculator 150 may calculate a phase difference between radio frequency signals reflected from at least two reflector antennas among the first reflector antenna 211, the second reflector antenna 212, the third reflector antenna 213, and the fourth reflector antenna 214. The phase difference calculator 150 may determine from which reflector antenna the reflected radio frequency signal (modulated radio frequency signal) is reflected based on the demodulation data output by the demodulator 140.

To this end, the transceiver device 100 may further include a memory 170. In the memory 170, information on the modulation frequency (f1) of the first modulator 240 and the modulation frequency (f2) of the second modulator may be stored in advance, and information on the arrangement of the reflector antennas may be stored.

Accordingly, the phase difference calculator 150 can determine from which reflector antenna the reflected radio frequency signal is reflected. This will be specifically described below.

Referring to FIG. 2, the radio frequency signal may be incident on the reflector device 200, modulated by the reflector device 200, and reflected to the transceiver device 100. The radio frequency signal incident on the first reflector antenna 211 is modulated by the first modulator 240 and reflected through the fourth reflector antenna 214. Conversely, the radio frequency signal incident on the fourth reflector antenna 214 is modulated by the first modulator 240 and reflected through the first reflector antenna 211.

Similarly, the radio frequency signal incident on the second reflector antenna 212 is modulated by the second modulator 250 and reflected through the third reflector antenna 213. Conversely, the radio frequency signal incident on the third reflector antenna 213 is modulated by the second modulator 250 and reflected through the second reflector antenna 212.

Due to such a VARA configuration, the incident radio frequency signal and the reflected radio frequency signal may have matching propagation paths as a whole.

However, when the reflector device 200 is rotated by a certain angle (Θ) with respect to a normal line of the propagation path, the reflector antennas 211, 212, 213, and 214 have delayed phases of 0, Φ1, Φ2, and Φ3, respectively.
Φ1 can be derived from the following equation according to the trigonometric formula.

Φ1=d sinΘ

The phase difference calculator 150 may extract delayed phases of 0, Φ1, Φ2, and Φ3 from the reflected radio frequency signal and calculate at least two phase differences. For example, Φ1−0 may be calculated, Φ2−Φ1 may be calculated, or Φ3−0 may be calculated. Various combinations may be possible.

The posture calculator 160 may calculate the posture of the object based on the phase difference. The posture may include orientation and positioning. The posture may include the position of the object on the XYZ axes and further the degree of rotation on the rotation axes of Roll (horizontal axis rotation), Pitch (frontal axis rotation), and Yaw (vertical axis rotation).

In FIG. 2, the posture calculator 160 may calculate the posture of the object, and the posture of the object may mean the posture of the reflector device 200. The present disclosure does not guarantee that it detects six degrees of freedom of an object as described above.

According to an embodiment, the posture calculator 160 may derive an angle (Θ) from the following equation based on the phase difference (Φ1−0) calculated by the phase difference calculator 150.

Θ=sin⁻¹(Φ1/d)

Also, based on the phase difference (Φ2−Φ1), the angle (Θ) may be derived from the following equation.

Θ=sin⁻¹[(Φ2−Φ1)/d]

In this way, the posture calculator 160 may calculate the degree of rotation of the reflector device 200 based on at least two phase differences calculated by the phase difference calculator 150. To calculate the phase difference, radio frequency signals reflected or transmitted from at least two of the plurality of reflector antennas may be appropriately selected and combined. Thereby, a precise posture can be measured or estimated.

According to an embodiment, the transceiver device 100 may further include a posture output unit 180. The posture output unit 180 may visually or audibly output the posture of the object to provide it to a user.

According to an additional aspect, in FIG. 2, the reflector device 200 may further include a modulation controller 260. The modulation controller 260 may control the first modulator 240 and the second modulator 250 to perform frequency modulation. The modulation controller 260 may control the first modulator 240 and the second modulator 250 to be sequentially activated or to be activated simultaneously.

The reflector device 200 may further include a power supply unit 270 for driving the modulation controller 260. For example, the power supply unit 270 may be a battery.

According to an additional aspect, in FIG. 2, a length (L1) of the first signal guide line between the first modulator 240 and the first reflector antenna 211 may be equal to a length (L1) of the first signal guide line between the first modulator 240 and the fourth reflector antenna 214.

Also, a length (L2) of the second signal guide line between the second modulator 250 and the second reflector antenna 212 may be equal to a length (L2) of the second signal guide line between the second modulator 250 and the third reflector antenna 213.

As such, by disposing the first modulator 240 and the second modulator 250 at intermediate positions of the lengths of the first signal guide line 220 and the first signal guide line 230, respectively, it may be advantageous to transmit radio frequency signals in phase from the first reflector antenna 211, the second reflector antenna 212, the third reflector antenna 213, and the fourth reflector antenna 214 from which radio frequency signals are both incident and reflected.

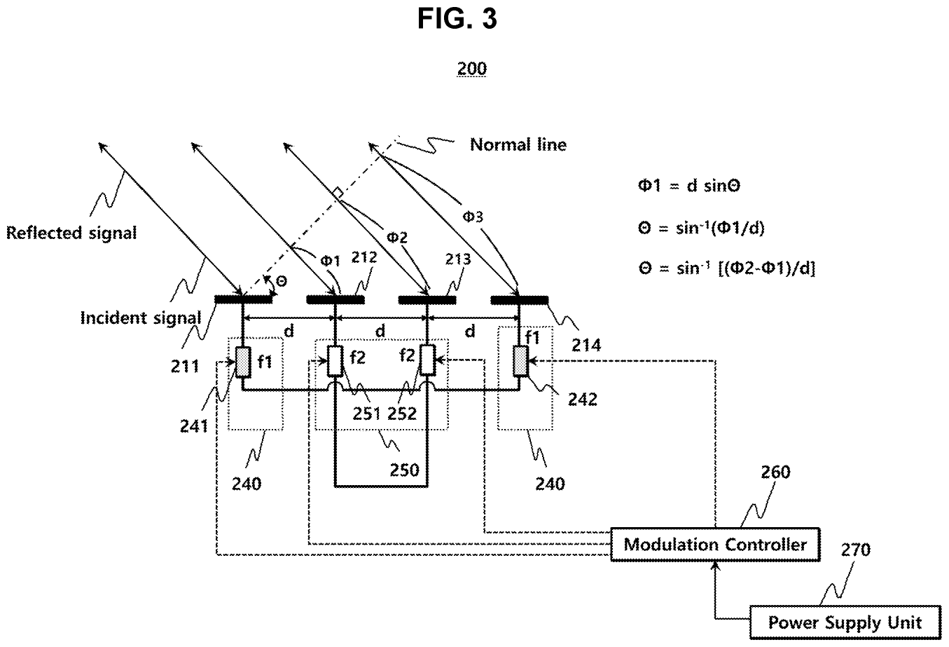

FIG. 3 illustrates a reflector device according to another embodiment. As shown, FIG. 3 illustrates the first modulator 240 and the second modulator 250 of FIG. 2 in more detail.

According to an embodiment, the first modulator 240 is divided into a first sub-modulator 241 of the first modulator and a second sub-modulator 242 of the first modulator, and the first sub-modulator 241 of the first modulator and the second sub-modulator 242 of the first modulator may be disposed adjacent to the first reflector antenna 211 and the fourth reflector antenna 214, respectively.

Also, the second modulator 250 is divided into a first sub-modulator 251 of the second modulator and a second sub-modulator 252 of the second modulator, and the first sub-modulator 251 of the second modulator and the second sub-modulator 252 of the second modulator may be disposed adjacent to the second reflector antenna 212 and the third reflector antenna 213, respectively.

According to an embodiment, when a radio frequency signal is incident on the first reflector antenna, the first sub-modulator 241 of the first modulator is controlled to be deactivated and the second sub-modulator 242 of the first modulator is controlled to be activated,
when a radio frequency signal is incident on the second reflector antenna, the first sub-modulator 251 of the second modulator may be controlled to be deactivated and the second sub-modulator 252 of the second modulator may be controlled to be activated.

Similarly, when a radio frequency signal is incident on the third reflector antenna 213, the modulation controller 260 controls the second sub-modulator 252 of the second modulator to be deactivated and the first sub-modulator 251 of the second modulator to be activated,
when a radio frequency signal is incident on the fourth reflector antenna 214, the second sub-modulator 242 of the first modulator may be controlled to be deactivated and the first sub-modulator 241 of the first modulator may be controlled to be activated.

In this way, each of the sub-modulators 241, 242, 251, and 252 is disposed adjacent to a corresponding reflector antenna 211, 212, 213, or 214, and the modulation controller 260 performs the activation and deactivation switching control to minimize phase errors due to propagation path differences and transmit in phase.

The meaning of being activated may mean a state (ON) in which the modulation function is performed, and the meaning of being deactivated may mean a state (OFF) in which the modulation function is not performed.

Although the present disclosure has been described above through embodiments referring to the accompanying drawings, it is not limited thereto and should be construed to encompass various modifications that can be obviously derived by those skilled in the art from them. The claims are intended to encompass such modifications.

What is claimed is:

1. A radio frequency communication system for detecting a posture of an object, the system comprising:
a transceiver device; and
a reflector device,
wherein the transceiver device comprises:
a signal generator configured to generate a radio frequency signal; and
a signal transmitter including a transmit antenna and configured to transmit the radio frequency signal toward the reflector device,
wherein the reflector device comprises:
a reflector antenna array including a first reflector antenna, a second reflector antenna, a third reflector antenna, and a fourth reflector antenna arranged at equal intervals on a substrate;
a first signal guide line electrically connecting the first reflector antenna and the fourth reflector antenna and having a predetermined length;
a second signal guide line electrically connecting the second reflector antenna and the third reflector antenna and having a predetermined length;
a first modulator disposed on the first signal guide line and configured to frequency-modulate a radio frequency signal incident on the first reflector antenna or the fourth reflector antenna; and
a second modulator disposed on the second signal guide line and configured to frequency-modulate a radio frequency signal incident on the second reflector antenna or the third reflector antenna.

2. The radio frequency communication system of claim 1, wherein the transceiver device further comprises:
a signal receiver including a receive antenna and configured to receive a frequency-modulated radio frequency signal from the reflector device;
a demodulator configured to demodulate the frequency-modulated radio frequency signal;
a phase difference calculator configured to calculate a phase difference between radio frequency signals reflected from at least two reflector antennas among the first reflector antenna, the second reflector antenna, the third reflector antenna, and the fourth reflector antenna; and
a posture calculator configured to calculate the posture of the object based on the phase difference.

3. The radio frequency communication system of claim 1, wherein the reflector device further comprises:
a modulation controller configured to control the first modulator and the second modulator to perform frequency modulation.

4. The radio frequency communication system of claim 1, wherein:
a length of the first signal guide line between the first modulator and the first reflector antenna is equal to a length of the first signal guide line between the first modulator and the fourth reflector antenna, and
a length of the second signal guide line between the second modulator and the second reflector antenna is equal to a length of the second signal guide line between the second modulator and the third reflector antenna.

5. The radio frequency communication system of claim 3, wherein:
the first modulator comprises a first sub-modulator of the first modulator and a second sub-modulator of the first modulator, wherein the first sub-modulator of the first modulator and the second sub-modulator of the first modulator are disposed adjacent to the first reflector antenna and the fourth reflector antenna, respectively, and
the second modulator comprises a first sub-modulator of the second modulator and a second sub-modulator of the second modulator, wherein the first sub-modulator of the second modulator and the second sub-modulator of the second modulator are disposed adjacent to the second reflector antenna and the third reflector antenna, respectively.

6. The radio frequency communication system of claim 5, wherein the modulation controller is configured to:
when the radio frequency signal is incident on the first reflector antenna, control the first sub-modulator of the first modulator to be deactivated and the second sub-modulator of the first modulator to be activated, and
when the radio frequency signal is incident on the second reflector antenna, control the first sub-modulator of the second modulator to be deactivated and the second sub-modulator of the second modulator to be activated.

7. The radio frequency communication system of claim 5, wherein the modulation controller is configured to:
when the radio frequency signal is incident on the third reflector antenna, control the second sub-modulator of the second modulator to be deactivated and the first sub-modulator of the second modulator to be activated, and
when the radio frequency signal is incident on the fourth reflector antenna, control the second sub-modulator of the first modulator to be deactivated and the first sub-modulator of the first modulator to be activated.
